(19) United States
(12) Patent Application Publication
(10) Pub. No.: US 2026/0309919 A1
(43) Pub. Date: Oct. 8, 2026

(54) GAP-FILL AND BOND FILM INTERFACE OPENING IN OPTICAL APPLICATIONS

(71) Applicant: Taiwan Semiconductor Manufacturing Co., Ltd., Hsinchu (TW)

(72) Inventors: Chia-Chun Kao, Taipei City (TW); Chia-Hsin Chen, Tainan City (TW); Chiahung Liu, Hsinchu (TW)

(21) Appl. No.: 19/716,523

(22) Filed: Jun. 23, 2026

Related U.S. Application Data
(63) Continuation of application No. 18/934,419, filed on Nov. 1, 2024.
(60) Provisional application No. 63/665,312, filed on Jun. 28, 2024.

(51) Int. Cl. G02B 6/132; G02B 6/124; G02B 6/136

(52) U.S. Cl. CPC G02B 6/132; G02B 6/1245; G02B 6/136

(57) ABSTRACT

A method includes etching a plurality of dielectric layers in a photonic die to form an opening. The opening overlaps a grating coupler, wherein the photonic die includes a first top surface at a first level. The method further includes forming a first dielectric region in the opening, attaching an electronic die to the photonic die, wherein the photonic die comprises a second top surface at a second level, and forming a gap-fill region to encircle the electronic die. The gap-fill region includes a second dielectric region that includes a first dielectric material, and the first dielectric material extends from the second level to the first level. A supporting substrate is bonded over the gap-fill region and the electronic die, wherein the supporting substrate includes a micro lens.

### PRIORITY CLAIM AND CROSS-REFERENCE

This application is a continuation of U.S. patent application Ser. No. 18/934,419, filed Nov. 1, 2024, and entitled “GAP-FILL AND BOND FILM INTERFACE OPENING IN OPTICAL APPLICATIONS,” which claims the benefit of U.S. Provisional Application No. 63/665,312, filed on Jun. 28, 2024, and entitled “GAP FILL & BONDING FILM INTERFACE OPENING (GBIO) DESIGN FOR OPTICAL TRANSMITTANCE,” which application are hereby incorporated herein by reference.

### BACKGROUND

Electrical signaling and processing are one of techniques for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIGS. 12A and 12B illustrate the views of intermediate stages in the formation of a package including a photonic die in accordance with some embodiments.

FIGS. 13-20 illustrate the views of intermediate stages in the formation of a package including a photonic die in accordance with alternative embodiments.

FIGS. 21-29 illustrate the views of intermediate stages in the formation of a package including a photonic die in accordance with alternative embodiments.

FIG. 30 illustrates a top view of some features in accordance with some embodiments.

FIG. 31 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a photonic die and the method of forming the same are provided. In accordance with some embodiments of the present disclosure, in the formation of the packages, an optical path is formed, and is used for conducting optical signals. The package may be formed of different dielectric materials such as silicon oxide and nitride. In accordance with some embodiments, a light-transparent material such as silicon oxide is selected. In the formation of the package, the materials that are different from the selected material are removed, and refilled with the selected light-transparent material. With the light path being comprising the selected light-transparent material rather than a plurality of different materials, the insertion loss caused by the different materials is reduced.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

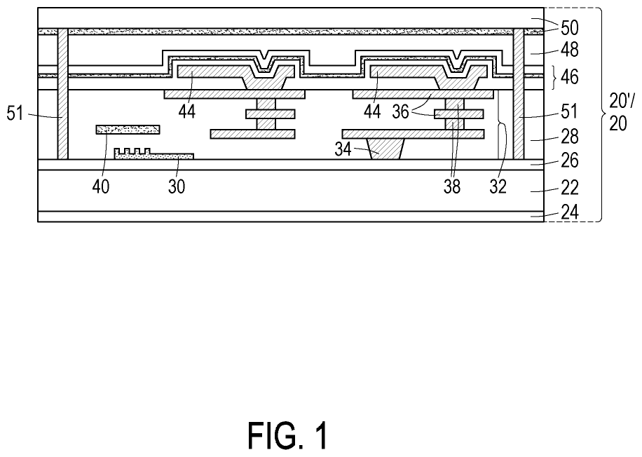

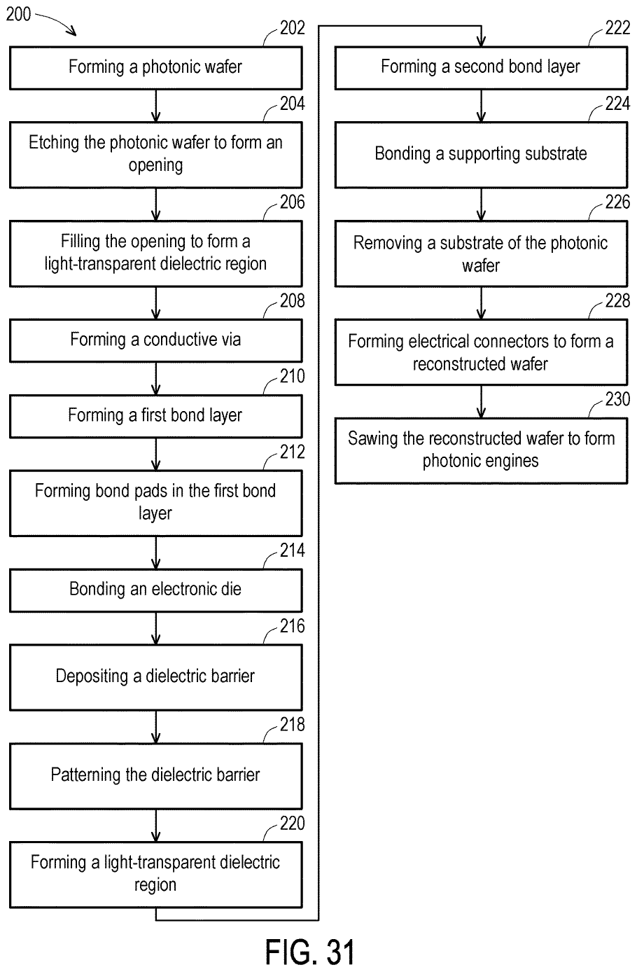

FIGS. 1 through 12A and 12B illustrate the cross-sectional views of intermediate stages in the formation of a package in accordance with some embodiments of the present disclosure. The corresponding processes are also reflected schematically in the process flow shown in FIG. 31.

Referring to FIG. 1, photonic die 20′ is formed. In accordance with some embodiments, photonic die 20′ is a part of an unsawed photonic wafer 20, which includes a plurality of photonic dies 20′ that are identical. The respective process is shown as process 202 in the process flow 200 as shown in FIG. 31. Photonic die 20′ is alternatively referred to as photonic Integrated circuit (PIC) die 20′.

Photonic die 20′ may include semiconductor substrate 22, which may be a silicon substrate in accordance with some embodiments. There may be, or may not be, a dielectric layer 24 underneath semiconductor substrate 22. Dielectric layer 26 is formed over semiconductor substrate 22. In accordance with some embodiments, dielectric layer 26 is an etch stop layer that is used in the subsequent formation of conductive features. The material of dielectric layer 26 may comprise silicon nitride, silicon oxynitride, silicon carbide, silicon oxycarbide, silicon oxide, or the like.

In accordance with some embodiments, photonic die 20′ may include integrated circuit devices (not shown) formed at a surface of semiconductor substrate 22. The integrated circuit devices (if formed) are used to support the functionality of the photonic die in accordance with some embodiments. The integrated circuit devices may include active devices such as transistors and/or diodes. The integrated circuit devices may also include passive devices such as capacitors, resistors, or the like. In accordance with alternative embodiments, no integrated circuit devices are formed in photonic die 20′.

Photonic die 20′ may include photonic devices such as waveguides, grating couplers, modulators, and/or the like. The waveguides may include silicon waveguides and/or silicon nitride waveguides. In accordance with some embodiments, dielectric layers 28 are formed, and may include silicon oxide, silicon oxynitride, aluminum oxide, aluminum nitride, or the like, or the like.

In accordance with some embodiments, the photonic devices may include grating coupler 30, which may be formed of silicon in accordance with some embodiments. For example, a silicon layer may be formed on dielectric layer 26, for example, by bonding a silicon layer to dielectric layer 26, followed by the patterning of the silicon layer through etching, so that waveguides, grating couplers, and the like are formed.

In accordance with some embodiments, dielectric layers 28 are formed over grating coupler 30. Dielectric layers 28 may comprise light-transparent and low-loss dielectric materials such as silicon oxide. In accordance with some embodiments, the dielectric layers underlying etch stop layer 40 (if formed) may include silicon oxide. The dielectric materials over etch stop layer may include a plurality of dielectric layers formed of different materials. The plurality of dielectric layers may include Inter-Metal Dielectric (IMDs), which may include a low-k dielectric material(s) such as porous silicon oxynitride. There may also be etch stop layers formed between the low-k dielectric materials. The etch stop layer may comprise AlN, AlO, SiON, or the like, or multi-layers thereof. It is appreciated that the formation of multiple layers using different materials will not cause insertion loss since these materials will be removed from the light path.

Interconnect structure 32 is formed, which may include metal via 34, vias 36, and metal lines 38 and the respective portions of dielectric layers 28. In accordance with some embodiments, metal via 34 has a bottom surface contacting dielectric layer 26. Metal via 34 may be formed through a damascene process such as a single damascene process. Vias 36 and metal lines 38 may be formed through single damascene processes and/or dual damascene processes.

For example, via 34, vias 36, and metal lines 38 may be formed through a single damascene process by forming openings in dielectric layers 28, and filling the openings with conductive materials. The conductive materials may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material. The remaining portions of the diffusion barrier layer and the metallic material form vias 34 and 36 and metal lines 38.

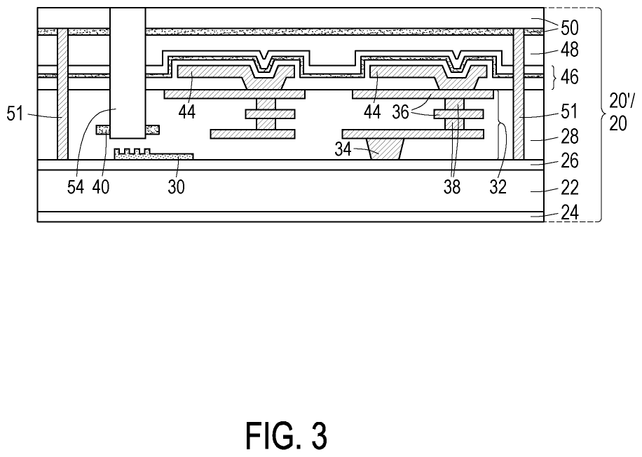

In accordance with some embodiments, etch stop layer 40 is formed directly over grating coupler 30 and inside dielectric layers 28. In accordance with alternative embodiments, etch stop layer 40 is not formed. The material of the etch stop layer 40 is different from the subsequently refilled dielectric region (FIG. 3). For example, etch stop layer 40 may be formed of or comprises silicon nitride, silicon oxynitride, silicon carbide, silicon oxycarbide, or the like, or may comprise a metal-containing material such as a metal oxide (aluminum oxide, for example). In accordance with some embodiments, the formation of etch stop layer 40 may include depositing a dielectric layer, and patterning the dielectric layer to remove some portions of the etch stop layer, leaving the portion of the etch stop layer directly over grating coupler 30 unremoved.

In accordance with some embodiments, metal pads 44 are formed over and electrically connected to interconnect structure 32. Metal pads 44 may be formed of aluminum copper, copper, nickel, or the like, or multi-layers thereof. Passivation layers 46 are formed over metal pads 44. In accordance with some embodiments, the formation of metal pads 44 may comprise depositing one of the passivation layers 46, forming openings in the passivation layer to expose the underlying metal pad in interconnect structure 32, depositing a metal seed layer, forming a plating mask, plating a metal layer, and performing an etching process to remove exposed portions of the metal seed layer. The remaining portions of the metal layer form metal pads 44. Each of the passivation layers 46 may have a single-layer structure or a multi-layer structure. For example, a passivation layer 46 may include a plurality of silicon oxide layers and a plurality of silicon nitride layers formed alternatingly.

A plurality of dielectric layers 48 and 50 are then formed. In accordance with some embodiments, the dielectric layer 48 may comprise an inorganic dielectric material such as silicon oxide, silicon nitride, silicon carbide, silicon oxynitride, or the like. The corresponding dielectric layer 48 may be formed through a deposition process, followed by a planarization process such as a Chemical Mechanical Polish (CMP) process or a mechanical grinding process.

Alternatively, dielectric layer 48 may be formed of or comprise an organic dielectric material, which may be a polymer such as polyimide, polybenzoxazole (PBO), benzocyclobutene (BCB), or the like. The corresponding process may include dispensing a polymer in a flowable form, and curing the polymer as a solid, followed by a planarization process. Dielectric layers 50 may also include silicon oxide, silicon nitride, silicon carbide, silicon oxynitride, or the like, and may also include etch stop layers. The top surface dielectric layer 50 may be planar, for example, formed by deposition and planarization.

In accordance with some embodiments, the wafer 20 (photonic die 20′) includes a device region and a ring region surrounding the device region. The interconnect structure 32 is disposed over the device region. A seal ring structure 51 is formed in a periphery region of photonic die 20′ and surrounding the interconnect structure. The device region may comprise a plurality of transistors (not shown) at the surface of and extending into substrate 22. The plurality of transistors are functionally connected by way of metal features in the interconnect structure.

The seal ring structure 51 comprises wall-like metal features extending continuously around the interconnect structure. The seal ring structure 51 comprises a plurality of conductive lines and conductive vias (not shown individually). The conductive lines and conductive vias are formed of a material including copper at an atomic percentage greater than 80% (in some embodiments, greater than about 90% or greater than about 95%)

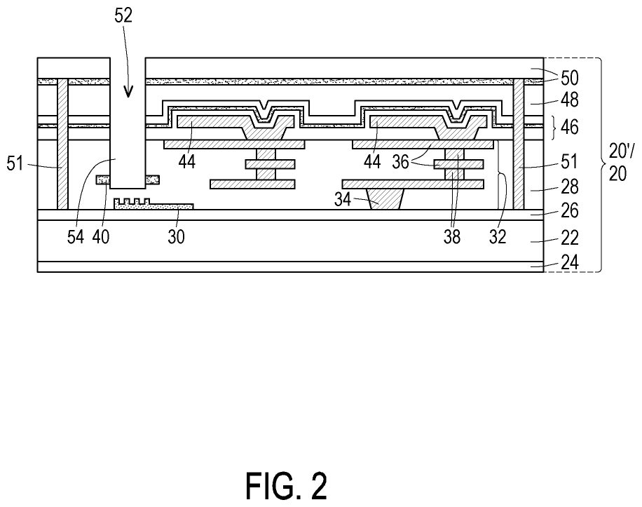

FIG. 2 illustrates an etching process to form opening 52, which penetrates through a plurality of dielectric layers in photonic die 20′. The respective process is shown as process 204 in the process flow 200 as shown in FIG. 31. In accordance with some embodiments, an etching mask (not shown) such as a photoresist is formed and patterned. The plurality of dielectric layers in photonic die 20′ are etched, forming opening 52. In accordance with some embodiments in which etch stop layer 40 is formed, the etching process stops on etch stop layer 40, followed by etching through etch stop layer 40 to reveal the underlying dielectric layer 28. In accordance with alternative embodiments in which etch stop layer 40 is not formed, a time mode etching process is adopted to ensure that the etching process stops when opening 52 has a desirable depth.

In accordance with some embodiments, the etching process is stopped when the dielectric layer(s) 28 underlying opening 52 (and thus between opening 52 and grating coupler 30) are all formed of a same (homogeneous material) such as silicon oxide. This may ensure the insertion loss of optical signal is minimized.

Referring to FIG. 3, opening 52 is filled with a light-transparent dielectric material. Dielectric region 54 is thus formed. The respective process is shown as process 206 in the process flow 200 as shown in FIG. 31. In accordance with some embodiments, dielectric region 54 comprises silicon oxide. In accordance with other embodiments, dielectric region 54 may comprise other dielectric materials such as silicon oxynitride. The elements other than silicon and oxygen may be low, for example, with the atomic percentage lower than about 10 percent or about 5 percent. The formation process may include depositing a dielectric layer to fully fill opening 52, and performing a planarization process such as a CMP process or a mechanical grinding process to remove excess portions of the dielectric layer.

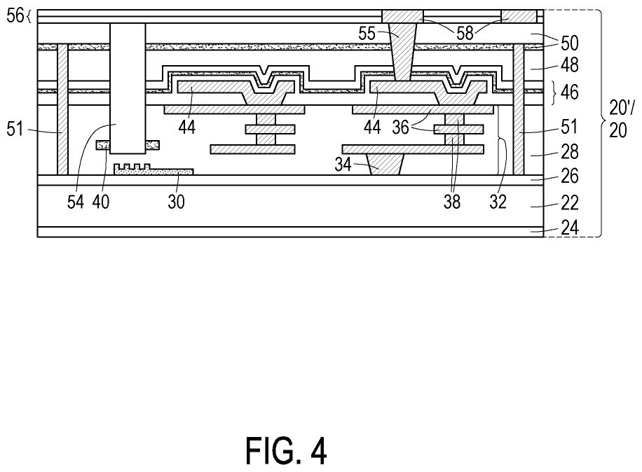

Referring to FIG. 4, conductive via 55 is formed. The respective process is shown as process 208 in the process flow 200 as shown in FIG. 31. Conductive via 55 may comprise a conductive material such as copper, tungsten, or the like, and may or may not include a diffusion barrier formed of Ti, TiN, Ta, TaN, or the like, or multi-layers. Conductive via 55 may land on metal pad 44 in accordance with some embodiments.

Referring to FIG. 4, bond layer 56 is formed. The respective process is shown as process 210 in the process flow 200 as shown in FIG. 31. In accordance with some embodiments, bond layer 56 may have a multi-layer structure or a single layer structure. The material of bond layer 56 may be the same as that of dielectric region 54. For example, bond layer 56 may comprise silicon oxide.

When formed of the same material as that of dielectric region 54, bond layer 56 may be formed using Atomic Layer Deposition (ALD), Chemical Vapor Deposition (CVD), or the like. Bond layer 56, when having the multi-layer structure, may have sub-layers having slightly different compositions. For example, one of the dielectric layers 56 may comprise silicon oxide, and the other may comprise silicon oxynitride. Alternatively, both of the dielectric layers 56 may comprise silicon oxynitride, but have oxygen atomic percentages different from each other.

Bond pads 58 are formed in dielectric layers 56. The respective process is shown as process 212 in the process flow 200 as shown in FIG. 31. In accordance with some embodiments, bond pads 58 may comprise copper, and may comprise a diffusion barrier, such as Ti, TiN, Ta, TaN, or the like. The formation process may include etching bond layer 56 to form openings, depositing a conductive material to fill the openings, and performing a planarization process to remove the portions of the conductive material over bond layer 56.

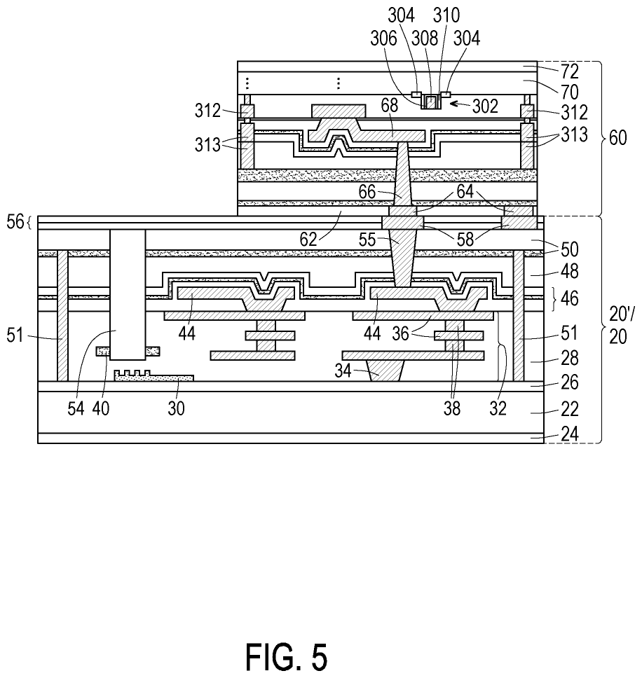

Referring to FIG. 5, another device die 60, which may be an Electronic Integrated circuit (EIC) die 60 (also referred to as an electronic die) or another type of die such as an independent passive device die, an Integrated Voltage Regulator (IVR) die, or the like is bonded to the photonic die 20′. The respective process is shown as process 214 in the process flow 200 as shown in FIG. 31. Throughout the description, die 60 is referred to as EIC die 60.

EIC die 60 may include metal pad 68, via 66 connected to metal pad 68, and bond pad 64 electrically connected to via 66. The metal pad 68 may be electrically connected to the integrated circuits in EIC die 60. In accordance with some embodiments, EIC die 60 includes a semiconductor substrate 70 (which may be a silicon substrate) and the integrated circuits formed on a surface of semiconductor substrate 70.

The integrated circuits may include active devices such as transistors, diodes, or the like, and may or may not include passive devices such as capacitors, inductors, resistors, or the like. For example, FIG. 5 schematically illustrates transistor 302. Transistor 302 may include source and drain regions 304, gate dielectric 306, gate electrode 308, and gate spacers 310 in accordance with some embodiments. The illustrated transistor 302 may represent the integrated circuits, and further represents both of n-type transistors and p-type transistors, which may be connected to form parts of the integrated circuits such as inverters.

It is appreciated that transistor 302 may represent any applicable type of transistors such as FinFETs, gate-all-around transistors, planar transistors, or the like. Dielectric layers 72 may be formed on semiconductor substrate 70. EIC die 60 further includes dielectric layer 62 as a bond layer, with bond pads 64 being formed in bond layer 62. In accordance with some embodiments, dielectric layers 72 may include seal ring 312/313 therein, which forms a full ring (when viewed in a bottom view of EIC die 60) that is proximate the peripheral regions of EIC die 60. Dielectric layer 72 may include low-k dielectric layers, which may be formed of carbon-containing dielectric layers, and may include pores therein.

In accordance with some embodiments, the EIC die 60 includes a device region and a ring region surrounding the device region. The interconnect structure 32 is disposed over (when EIC die 60 is viewed upside down) the device region. Seal ring structure seal ring 312/313 (including seal ring parts 312 and 313) is formed in a periphery region of seal ring 312/313 and surrounding the interconnect structure. The device region may comprise a plurality of transistors (not shown) at the surface of and extending into substrate 70. The plurality of transistors are functionally connected by way of metal features in the interconnect structure.

The seal ring structure 312/313 comprises wall-like metal features extending continuously around the interconnect structure. The seal ring structure 312/313 comprises a plurality of conductive lines and conductive vias (not shown individually). The conductive lines and conductive vias are formed of a material including copper at an atomic percentage greater than 80% (in some embodiments, greater than about 90% or greater than about 95%.)

The bonding between the photonic die 20′ and the EIC die 60 may include metal-to-metal direct bonding, solder bonding, or hybrid bonding that includes both of metal-to-metal direct bonding and fusion bonding. For example, the bond layer 62 is bonded to bond layer 56 through fusion bonding. In accordance with some embodiments, the material of bond layer 62 is different from the material of bond layer 56, so that heterogenous bonding may be achieved to improve the bonding strength.

In accordance with some embodiments, the EIC die 60 may include integrated circuits (not shown) for communicating with the photonic die 20′, such as the circuits for controlling the operation of the photonic die 20′. For example, the EIC die 60 may include controllers, drivers, amplifiers, the like, or combinations thereof. the EIC die 60 may also include a CPU. In accordance with some embodiments, the EIC die 60 includes the circuits for processing electrical signals received from the photonic die 20′. The EIC die 60 may also control high-frequency signaling of the photonic die 20′ according to electrical signals (digital or analog) received from another device or die. In accordance with some embodiments, the EIC die 60 may include a circuit that provides Serializer/Deserializer (SerDes) functionality. In this manner, the EIC may act as a part of an I/O interface between optical signals and electrical signals.

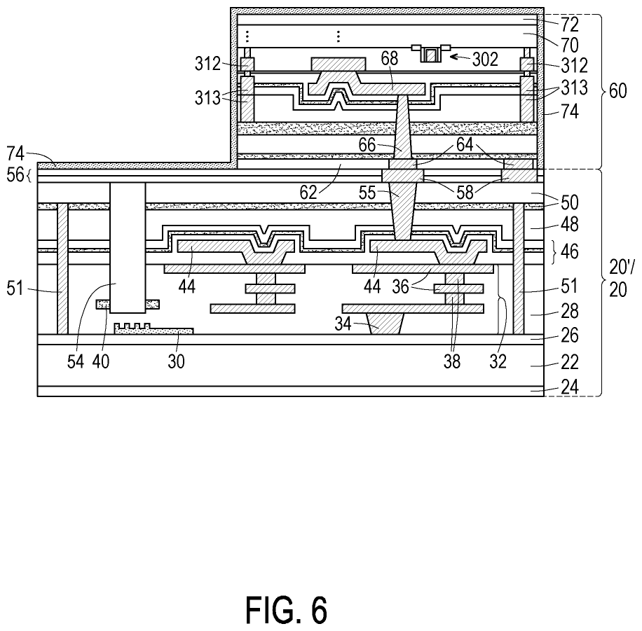

It is appreciated that the processes as illustrated in FIGS. 1 through 5 are at wafer level, wherein a plurality of EIC dies 60 may be bonded to a plurality of photonic dies 20′ of photonic wafer 20 in accordance with some embodiments. FIGS. 6 through 8 illustrate a gap-fill process in accordance with some embodiments, wherein the gaps between EIC dies 60 are filled to form dielectric regions (that encircle the EIC dies 60), which are also referred to as gap-fill regions.

Referring to FIG. 6, dielectric barrier 74 is deposited. The respective process is shown as process 216 in the process flow 200 as shown in FIG. 31. The deposition process includes a conformal deposition process such as ALD, CVD, or the like. The material of dielectric barrier 74 is selected to have good adhesion ability on EIC dies 60. In accordance with some embodiments, dielectric barrier 74 is formed of or comprise silicon nitride, silicon carbo-nitride, silicon oxynitride, silicon carbide, or the like, which material may be different from the material of dielectric region 54 and the bond layer 56.

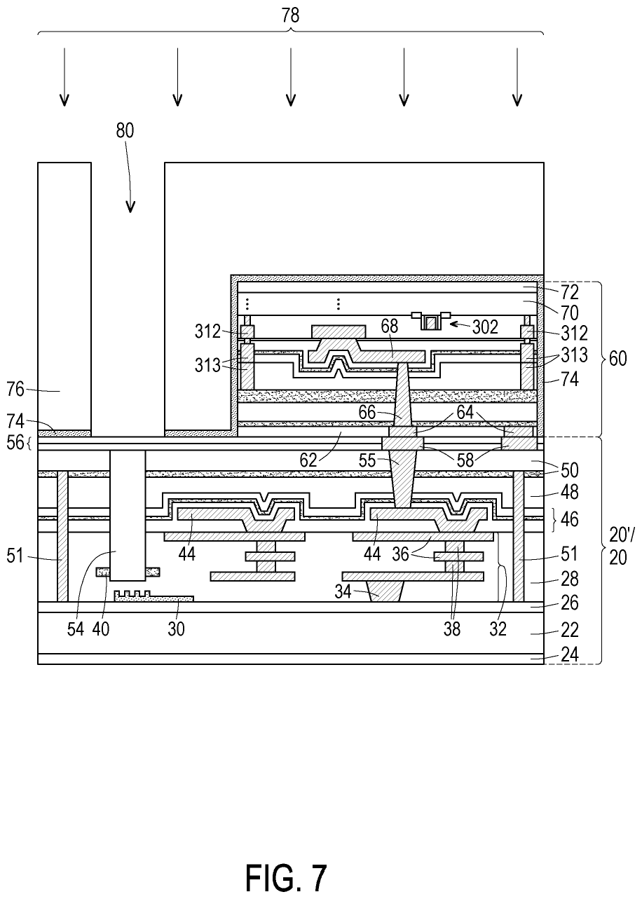

Referring to FIG. 7, etching mask 76 is formed, which may be formed of a patterned photoresist. Etching process 78 is performed to etch and pattern dielectric barrier 74, so that opening 80 is formed, and the underlying bond layer 56 is exposed. The respective process is shown as process 218 in the process flow 200 as shown in FIG. 31. The etching process 78 is performed using bond layer 56 as an etch stop layer, so that opening 80 extends into dielectric barrier 74, and bond layer 56 is exposed. In accordance with some embodiments, the entire opening 80 is directly over bond layer 56, and no metal feature in bond layer 56 is exposed to opening 80. After the etching process 78, etching mask 76 is removed, for example, through an ashing process.

In accordance with alternative embodiments, as a result of the etching process 78, bond layer 56 is etched through, and the underlying dielectric region 54 is exposed. This embodiment may be adopted when bond layer 56 has a different material from that of dielectric region 54.

In accordance with alternative embodiments, instead of using an etching mask 76 to perform the patterning process, the patterning of dielectric barrier 74 may be performed through an anisotropic etching process to etch dielectric barrier 74. As a result, the horizontal portions of the dielectric barrier 74 are removed from the exposed top surfaces of wafer 20. The vertical portions of the dielectric barrier 74 on the sidewalls of the EIC dies 60, however, are left on the sidewalls of, and encircling, the EIC dies 60.

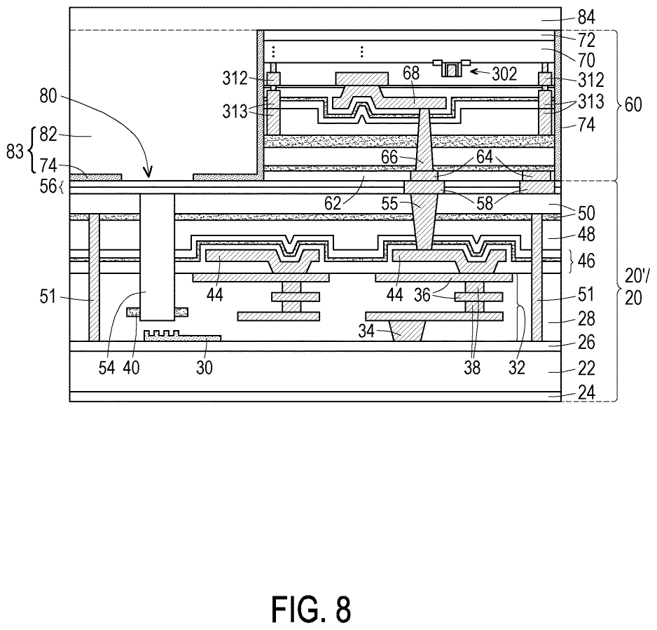

Referring to FIG. 8, dielectric region 82, which is light-transparent, is formed. The respective process is shown as process 220 in the process flow 200 as shown in FIG. 31. In accordance with some embodiments, the formation process may include depositing a dielectric material, and performing a planarization process such as a CMP process or a mechanical grinding process on the deposited dielectric material. The planarization process may use dielectric barrier 74 or semiconductor substrate 70 as a CMP stop layer.

The dielectric material of dielectric region 82 may comprise silicon oxide, silicon oxynitride, or the like. The dielectric material (such as silicon oxide) of dielectric region 82 may also be the same as that of bond layer 56, dielectric region 54, and the portion of the dielectric layer 28 directly under dielectric region 54. Throughout the description, dielectric barrier 74 and dielectric region 82 are collectively referred to as gap-fill region 83.

Next, bond layer 84 is formed through a deposition process. The respective process is shown as process 222 in the process flow 200 as shown in FIG. 31. In accordance with some embodiments, bond layer 84 is formed of or comprise silicon oxide, silicon oxynitride, or the like. In accordance with some embodiments, bond layer 84 is formed of a same material as that of dielectric region 82. Bond layer 84 and dielectric region 82 may be, or may not be, distinguishable from each other, and may or may not include distinguishable interface in between. Accordingly, the interface between bond layer 84 and dielectric region 82 is shown as being dashed to indicate that the interface may be or may not be distinguishable.

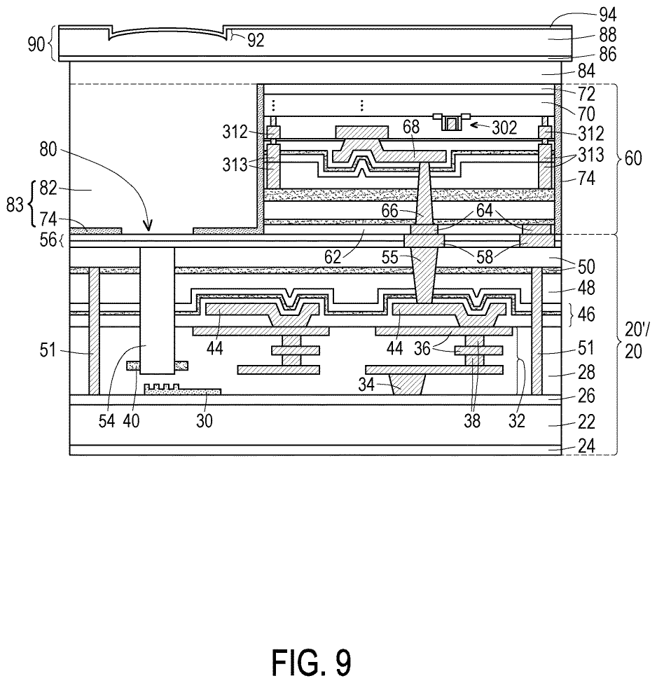

Referring to FIG. 9, supporting substrate 90 (which may be a wafer) is bonded to bond layer 84. The respective process is shown as process 224 in the process flow 200 as shown in FIG. 31. In accordance with some embodiments, supporting substrate 90 includes bond layer 86, and silicon substrate 88 attached to bond layer 84. Bond layer 86 may be formed of or comprise a silicon-containing dielectric material such as silicon oxide, silicon oxynitride, silicon carbo-nitride, or the like. The bonding may include fusion bonding, with bond layer 86 being bonded to bond layer 84. In accordance with some embodiments, the material of bond layer 86 is close to or the same as that of bond layer 84 and dielectric regions 82 and 54, for example, including silicon oxide.

In accordance with some embodiments, supporting substrate 90 includes micro lens 92, which is formed as a part of silicon substrate 88, for example, through etching silicon substrate 88. Supporting substrate 90 further includes protection layer 94 formed on silicon substrate 88. Protection layer 94 further includes a portion in the recess in silicon substrate 88, in which micro lens 92 is formed. Protection layer 94 may be a conformal layer formed of silicon oxide. Micro lens 92 is vertically aligned to dielectric region 82, opening 80 in dielectric barrier layer 74, dielectric region 54, and grating coupler 30 in accordance with some embodiments.

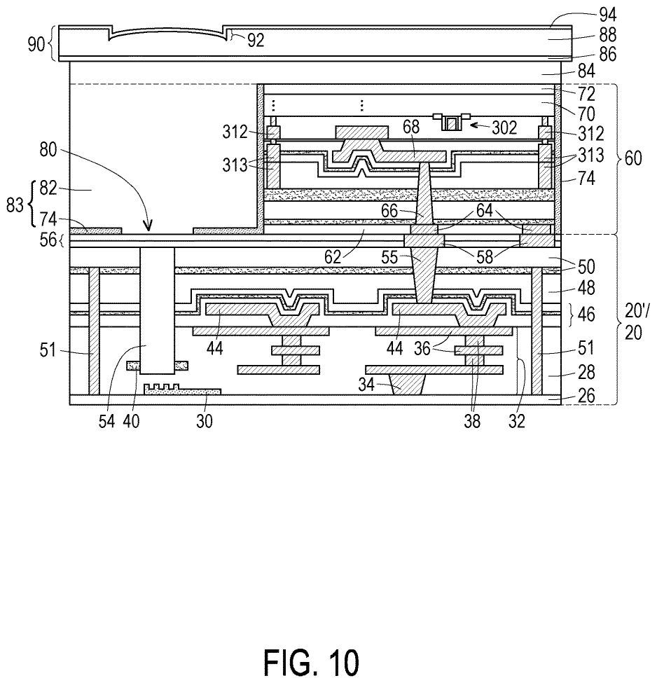

Next, the semiconductor substrate 22 and dielectric layer 24 are removed. The respective process is shown as process 226 in the process flow 200 as shown in FIG. 31. The resulting structure is shown in FIG. 10. In accordance with alternative embodiments in which photonic die 20′ include active devices, the dielectric layer 24 and semiconductor substrate 22 may remain. The removal process (if performed) may include a CMP process, a mechanical grinding process, or the like. Accordingly, dielectric layer 26 is exposed.

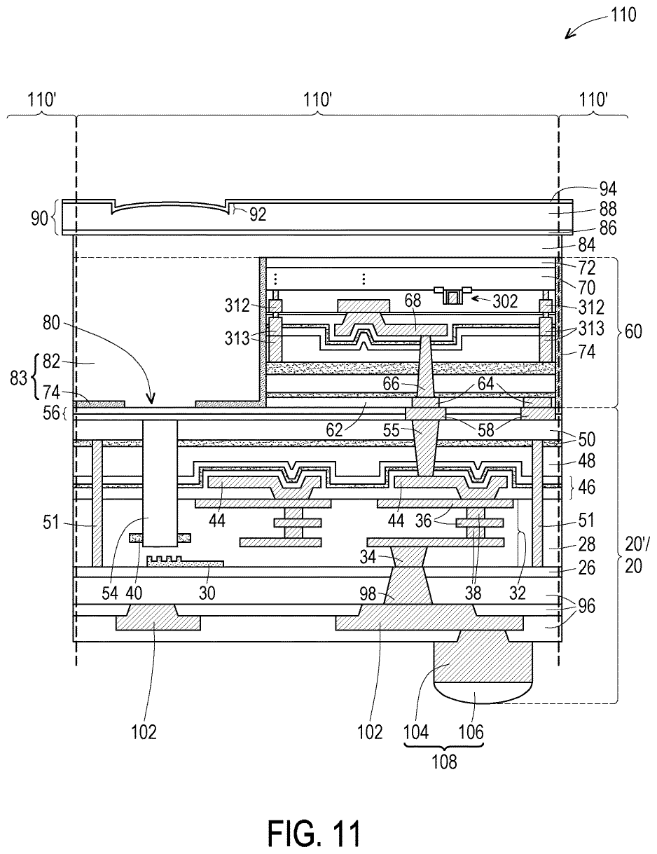

In subsequent processes, as shown in FIG. 11, dielectric layers 96 are formed on dielectric layer 26. Dielectric layers 96 may include inorganic dielectric materials such as silicon oxide, silicon nitride, or the like, and/or organic dielectric materials such as polymers. The polymers may include polyimide, PBO, BCB, or the like. Conductive features such as vias 98 and metal pads 102 are formed in dielectric layers 96. Electrical connectors 108 may then be formed. The respective process is shown as process 228 in the process flow 200 as shown in FIG. 31. In accordance with some embodiments, electrical connectors 108 may include metal pillars 104 and solder regions 106. Reconstructed wafer 110 is thus formed.

In a subsequent process, a sawing process (also referred to as a singulation process) is performed to saw reconstructed wafer 110 and to form a plurality of optical engines 110′, which are also referred to as Compact Universal Photonic Engines (COUPEs) or packages. The respective process is shown as process 230 in the process flow 200 as shown in FIG. 31. The plurality of optical engines 110′ are identical, and each may include a PIC die 20′, an EIC die 60, and a supporting substrate 90, which is sawed from the wafer-level supporting substrate 90.

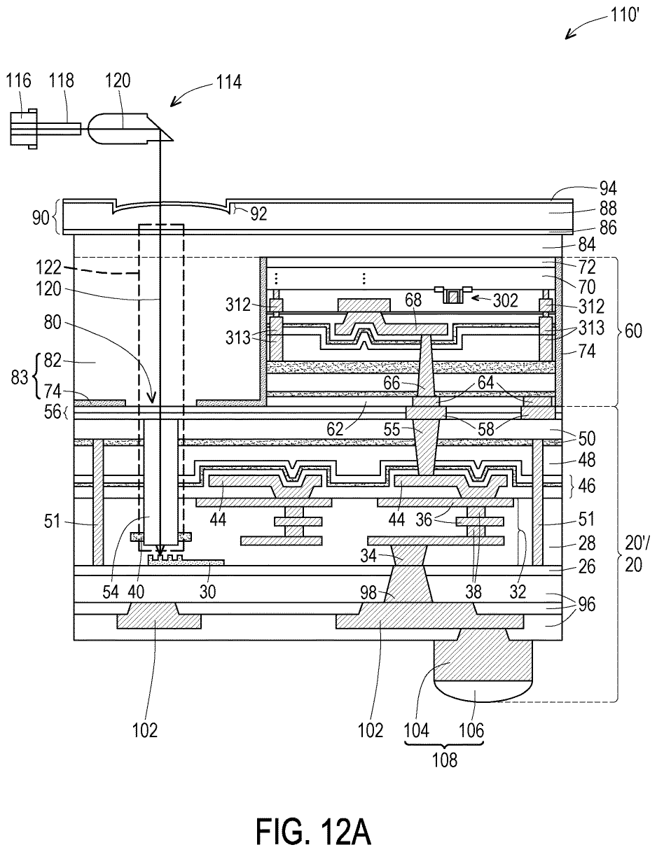

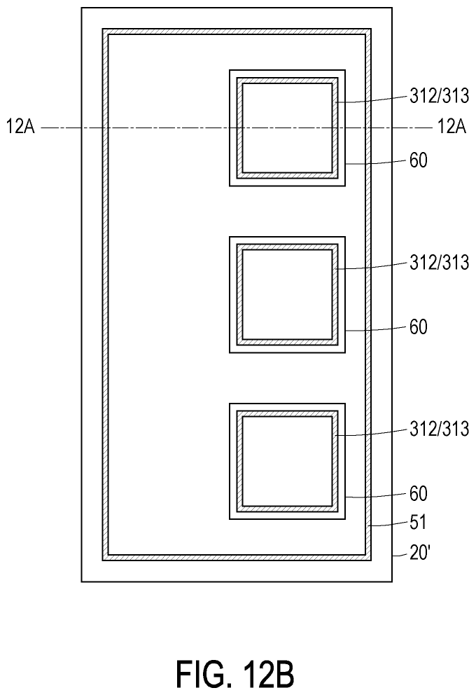

FIG. 12A illustrates the usage of photonic engine 110′ in accordance with some embodiments. Photonic engine 110′ may be bonded to a package component (not shown) underlying and electrically connected to photonic engine 110′. The underlying package component may include an interposer, a package substrate, a printed circuit board, or the like. A fiber assembly unit (FAU) 114 is attached to the underlying structure. An optical fiber 118 is attached to a fiber connector 116.

A laser beam 120 may be projected out of optical fiber 118, and reflected in FAU 114. The laser beam 120 is reflected by a reflecting surface, and is projected to micro lens 92. The laser beam 120 passes through optical path 122 to reach grating coupler 30, which conducts the optical signal into waveguides. The optical signals carried by the laser beam 120 are further processed by photonic die 20′ and EIC die 60. For example, the optical signals may alternatively be converted to electrical signal by the photonic die 20′, and the electrical signals are transferred to EIC die 60.

In accordance with some embodiments, as shown in FIG. 12A, laser beam 120 for carrying optical signals, after converged by micro lens 92, passes through an optical path 122 to reach grating coupler 30. The optical path 122 includes some portions of bond layers 84 and 86, dielectric region 82, bond layer 56, dielectric region 54, and dielectric layer 28. In accordance with the embodiments of the present disclosure, the entire optical path 122 is formed using a same material (such as silicon oxide), or materials (such as silicon oxide and silicon oxynitride) have small differences. Also, by using a homogenous dielectric region 54 to replace the otherwise heterogenous dielectric layers 28, 46, 48, and 50, the difference in materials is eliminated, and insertion loss in photonic die 20′ is eliminated.

Also, by forming opening 80 in dielectric barrier 74, the otherwise high insertion loss material is removed from the optical path 122. Accordingly, the entire optical path 122 may be formed of the materials that either the same as each other, or with small differences. For example, if silicon oxynitride is used as a part of the optical path 122 along with silicon oxide, the nitrogen atomic percentage may be lower than about 10 percent or 5 percent. The insertion loss in the entire optical path 122 is thus low.

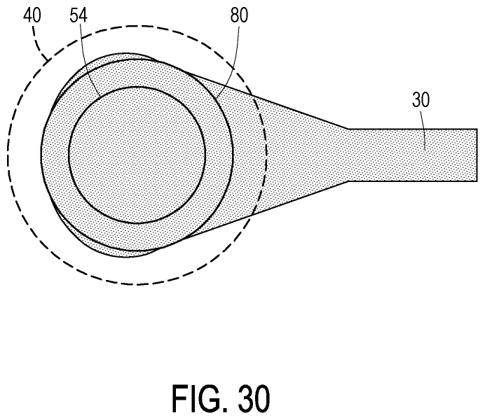

FIG. 30 illustrates a top view of some features in accordance with some embodiments. In accordance with some embodiments, opening 80 is larger than dielectric region 54 in the top view, and dielectric barrier 74 extends from opening 80 in all lateral directions as shown in FIG. 30. Etch stop layer 40, if formed, may have the shape of a ring encircling dielectric region 54.

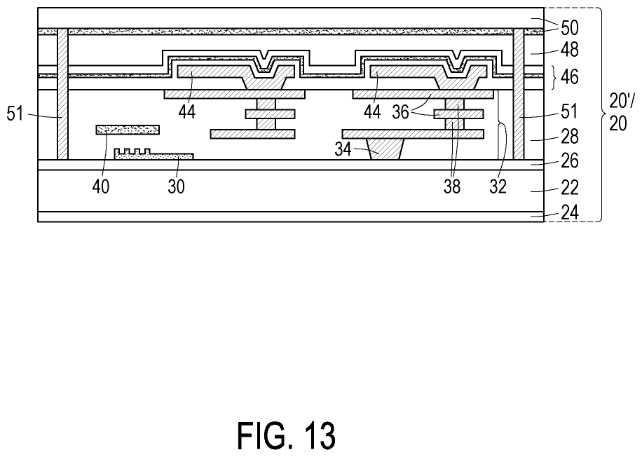

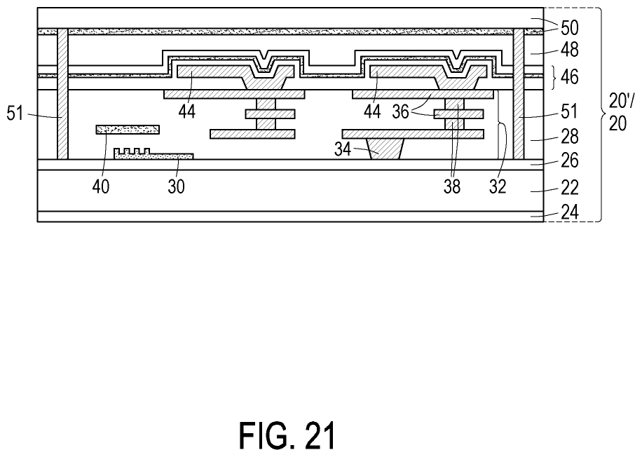

FIGS. 13 through 20 illustrate the cross-sectional views of intermediate stages in the formation of a photonic engine in accordance with alternative embodiments. These embodiments are similar to the embodiments as shown in FIGS. 1 through 12A and 12B, except that instead of depositing and then patterning a dielectric barrier, the dielectric barrier is not deposited. Unless specified otherwise, the materials, the structures, and the formation processes of the components in these embodiments (and the embodiments shown in FIGS. 21-29) are essentially the same as the like components denoted by like reference numerals in the preceding embodiments. The details regarding the materials, the structures, and the formation processes provided in each of the embodiments throughout the description may be applied to any other embodiment whenever applicable.

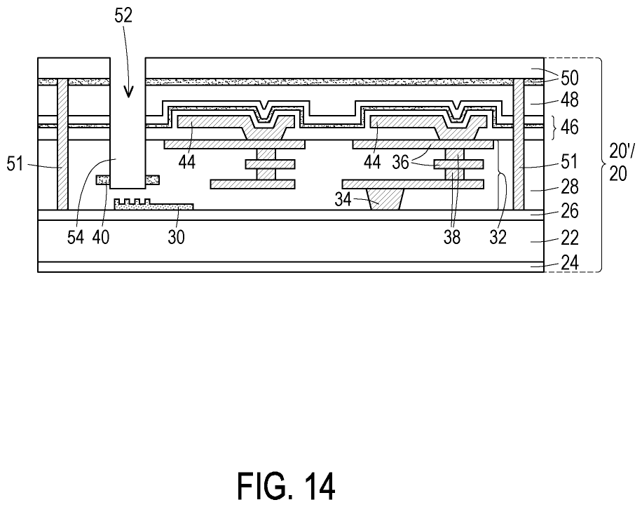

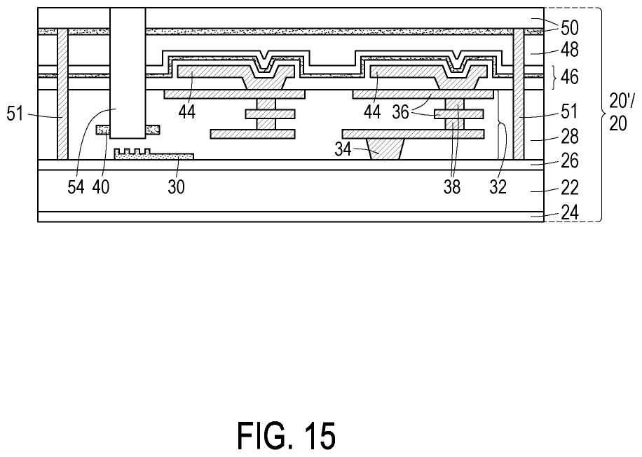

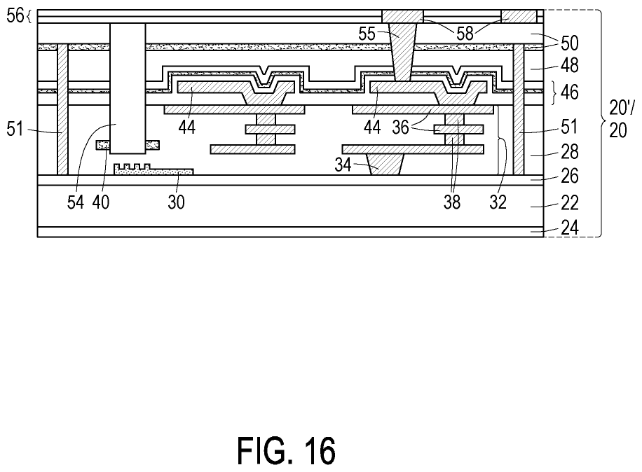

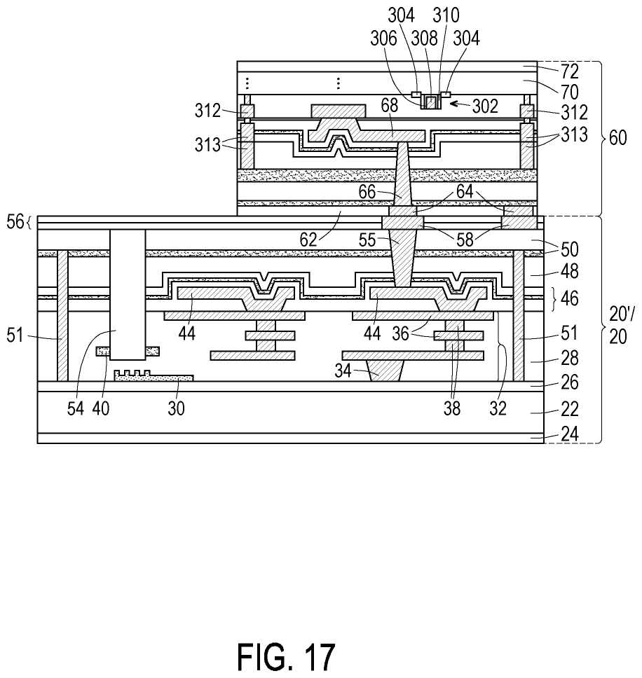

The initial steps of these embodiments are shown in FIGS. 13, 14, 15, 16, and 17, and are essentially the same as shown in FIGS. 1, 2, 3, 4, and 5, respectively. The process steps include the formation of photonic wafer 20 (including photonic die 20′ therein) as shown in FIG. 13, etching dielectric layers to form an opening 52 (FIG. 14), filling opening 52 with a transparent dielectric region 54 (FIG. 15), and forming additional dielectric layers, vias, bond pads, and the like (FIG. 16). FIG. 17 illustrates the bonding of EIC die 60 to phonic die 20′. It is appreciated that although one EIC die 60 is illustrated, a plurality of EIC dies 60, which may be identical, are bonded to photonic wafer 20.

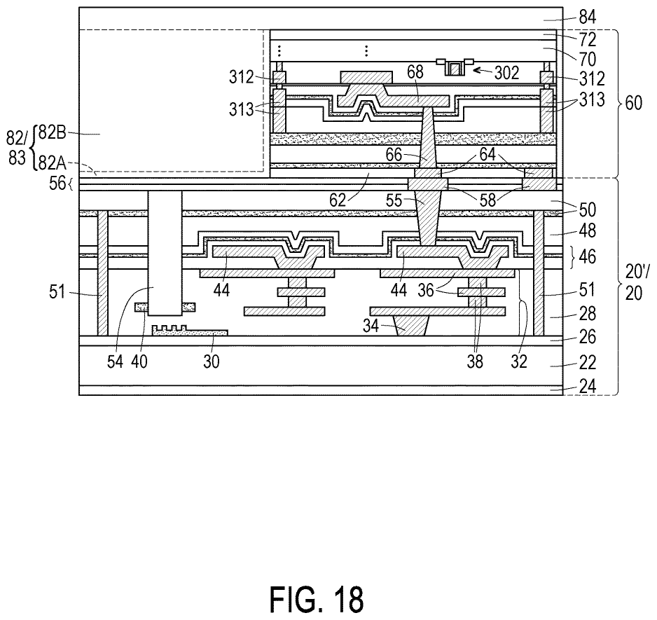

Referring to FIG. 18, gap-fill region 82 is formed as a barrier-less gap-fill region 83. In accordance with some embodiments, without forming any barrier layer, the entire dielectric region 82 is formed of a homogeneous dielectric material such as silicon oxide, silicon oxynitride, or the like. The formation of the entire dielectric region 82 may include a continuous deposition process such as ALD, CVD, or the like. Accordingly, there is no distinguishable interfaces inside dielectric region 82.

In accordance with alternative embodiments, the formation of dielectric region 82 may include depositing two sub layers 82A and 82B using different deposition methods, while sub layers 82A and 82B are formed of a same dielectric material such as silicon oxide. Alternatively, sub layers 82A and 82B are formed of silicon oxynitride, with the sub layers 82A and 82B having the same nitrogen atomic percentage and the same oxygen atomic percentage, and silicon atomic percentage.

In accordance with some embodiments, sub layer 82A may be formed using a conformal deposition process such as ALD, CVD, or the like, and sub layer 82B may be formed using a different process (such as a bottom-up deposition process such as FCVD).

In the embodiments in which sub layers 82A and 82B are formed of the same dielectric material using different deposition methods, the property of the dielectric material of sub layer 82A may be different from the property of the dielectric material of sub layer 82B. For example, sub layer 82A may be denser than sub layer 82B when sub layer 82A is formed using ALD, and when sub layer 82B is formed using Flowable Chemical Vapor Deposition. The sub layer 82A may thus act as the barrier and the adhesion layer.

In FIG. 18, the interface between sub layers 82A and 82B is shown as being dashed to indicate that dielectric region 82 may be a homogeneous region formed of the same dielectric material using the same deposition method, or may include sub layers formed using different methods.

In a subsequent process, a planarization process is performed on dielectric region 82, followed by the formation of bond layer 84, as also shown in FIG. 18.

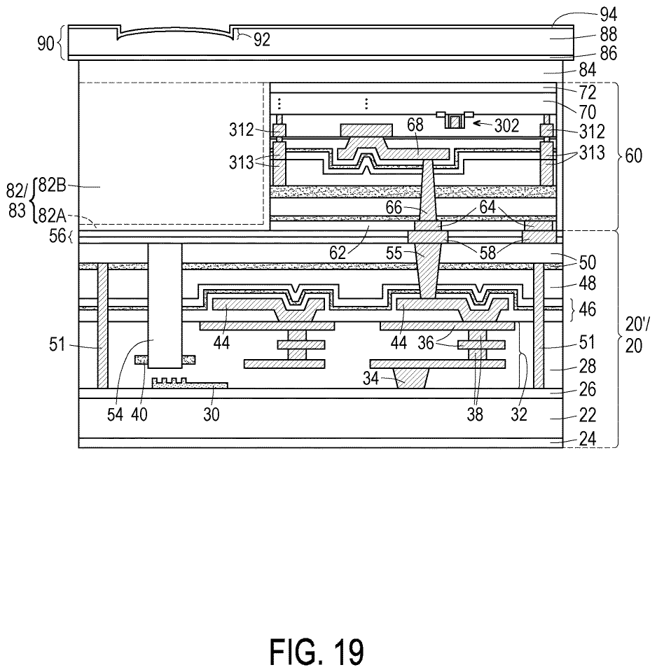

FIG. 19 illustrates the bonding of supporting substrate 90 to the underlying structure. The bonding may be achieved through fusion bonding, with bond layer 86 being bonded to bond layer 84. In a subsequent process, the semiconductor substrate 22 and dielectric layer 24 in photonic wafer 20 are removed, exposing dielectric layer 26.

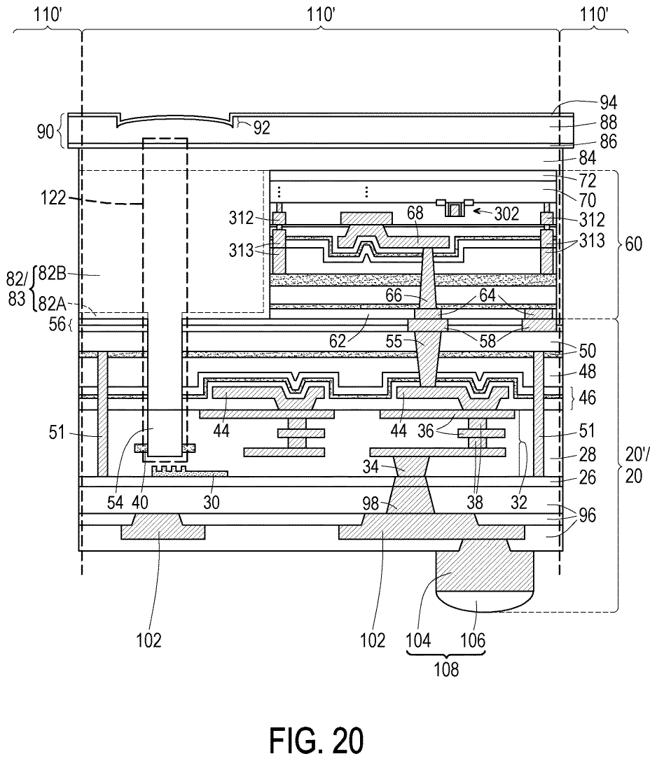

FIG. 20 illustrates the subsequent processes, including the formation of dielectric layers 96, via 98, metal pads 102 and electrical connectors 108. Reconstructed wafer 110 is thus formed. A sawing process is then performed to saw the reconstructed wafer 110 into a plurality of optical engines 110′. The usage of optical engine 110′ is similar to what is shown in FIG. 12A.

In accordance with these embodiments, the optical path of the optical signals received into the optical engine 110′ is formed of essentially the same light-transparent dielectric material (such as silicon oxide), or dielectric materials that have small differences. For example, when silicon oxynitride is used as a part of the optical path along with silicon oxide, the nitrogen atomic percentage may be lower than about 10 percent or 5 percent.

FIG. 12B illustrates a top view of the structure shown in FIG. 12A in accordance with some embodiments. The top view as shown in FIG. 12B may also be the top views of the structures shown in FIG. 20. The photonic die 20′ and EIC die 60 and the respective seal rings 51 and 312/313 are also illustrated.

FIGS. 21 through 29 illustrate the cross-sectional views of intermediate stages in the formation of a photonic engine in accordance with yet alternative embodiments. These embodiments are similar to the embodiments as shown in FIGS. 1 through 12A and 12B, except that the dielectric region 54 in photonic die is replaced in a same step as the gap-filling process. The details regarding the materials, the structures, and the formation processes in accordance with these embodiments throughout the description may be essentially the same as the preceding embodiments.

The initial steps of these embodiments are shown in FIG. 21, and are essentially the same as shown in FIG. 1, in which photonic wafer 20 (including photonic die 20′ therein) is formed.

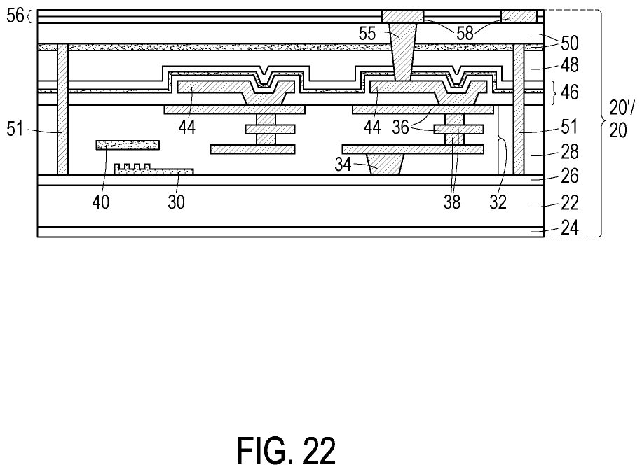

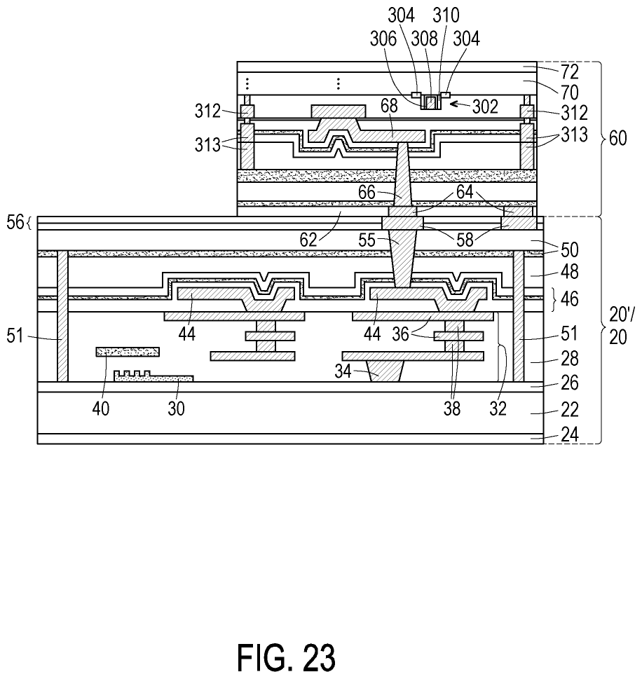

Referring to FIG. 22, dielectric layers 48 and 50 are formed, followed by the formation of via 55. Bond layer 56 and bond pads 58 are then formed. Next, as shown in FIG. 23, EIC die 60 is bonded to photonic die 20′.

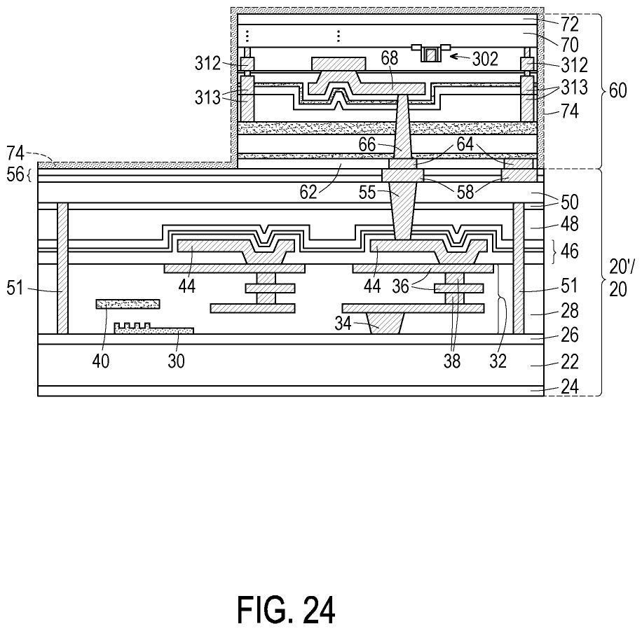

In a subsequent process, as shown in FIG. 24, dielectric barrier 74 (also an adhesion layer) may be formed as a conformal layer in a conformal deposition process. The material and the formation process of dielectric barrier 74 may be found referring to preceding embodiments. In accordance with alternative embodiments, dielectric barrier 74 is not formed. Accordingly, dielectric barrier 74 is illustrated as being dashed to indicate that it may, or may not be formed.

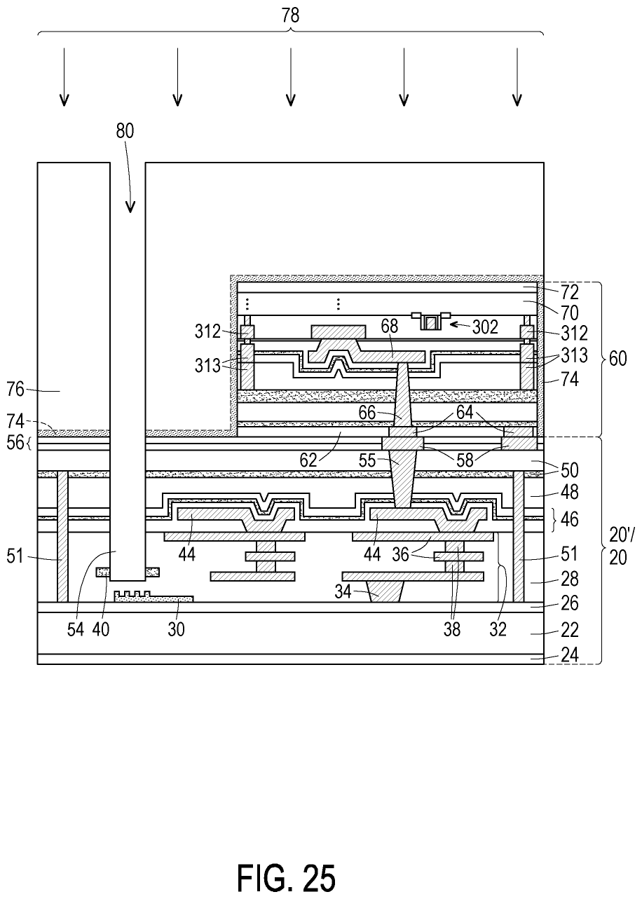

Next, referring to FIG. 25, etching mask 76 is formed and patterned, with opening 80 formed therein. An etching process(es) is then performed to etch dielectric barrier 74 (if formed) and the underlying photonic die 20′, so that opening 80 penetrates through a plurality of dielectric layers in photonic die 20′, with the plurality of dielectric layers being formed of different dielectric materials. The opening 80 may penetrate through etch stop layer 40, and land on a bottom layer of dielectric layers 28. The dielectric layer(s) 28 between opening 80 and grating coupler 30 may be formed of a homogeneous transparent material such as silicon oxide.

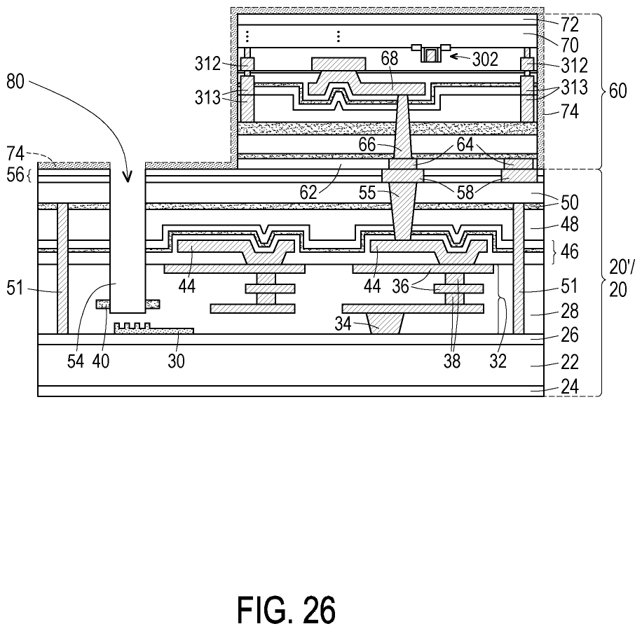

After the etching process, etching mask 76 is removed. The resulting structure is shown in FIG. 26.

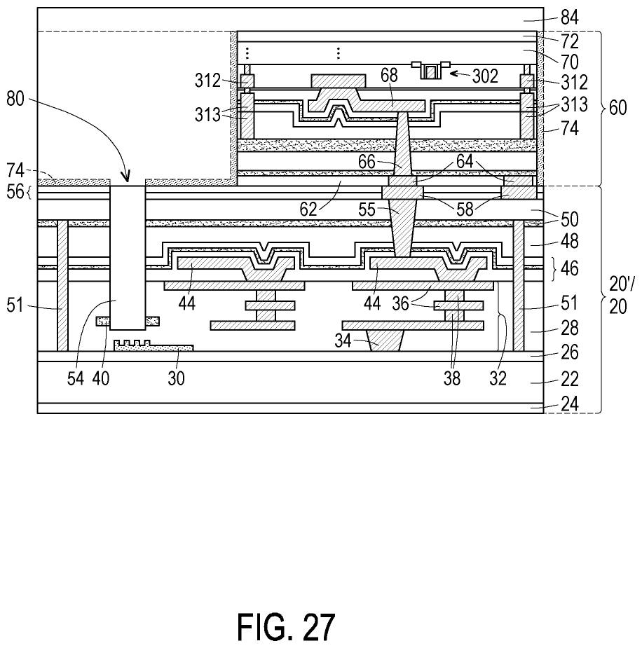

In a subsequent process, a dielectric material is deposited to fill opening 80 and the gaps between neighboring EIC dies 60. The resulting structure is shown in FIG. 27. The deposition process may be a single and continuous deposition process with no break in between. The filled dielectric material thus may be homogeneous. In accordance with some embodiments, the dielectric material comprises silicon oxide or silicon oxynitride.

A planarization process is then performed to remove the portions of the dielectric material over EIC dies 6o. The remaining portion of the dielectric material include dielectric region 54 in photonic die 20′ and dielectric region 82 aside of EIC die 60. Gap-fill region 83 is thus formed. It is appreciated that dielectric region 54 is continuously connected to dielectric region 82, with no distinguishable interface in between. In a subsequent process, bond layer 84 is formed, as also shown in FIG. 27.

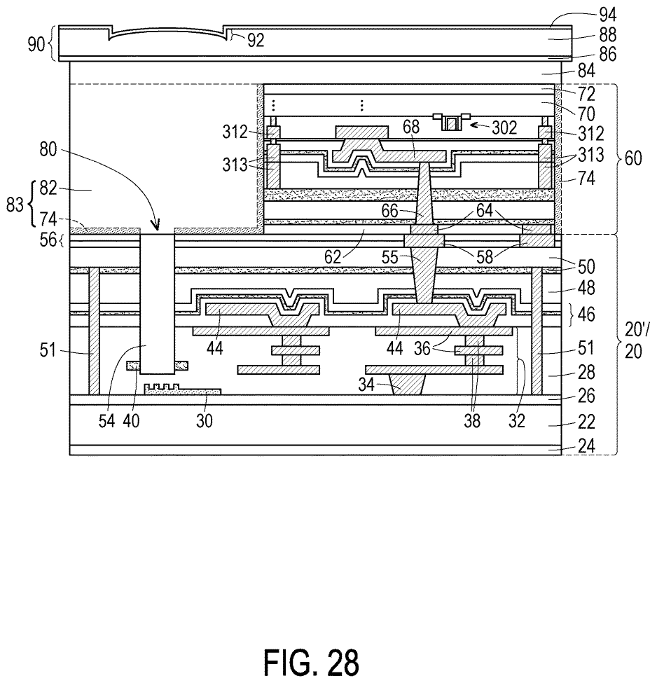

FIG. 28 illustrates the bonding of supporting substrate 90 to the underlying structure. The bonding may be achieved through fusion bonding, with bond layer 86 being bonded to bond layer 84. In a subsequent process, the semiconductor substrate 22 and dielectric layer 24 in photonic wafer 20 are removed, exposing dielectric layer 26.

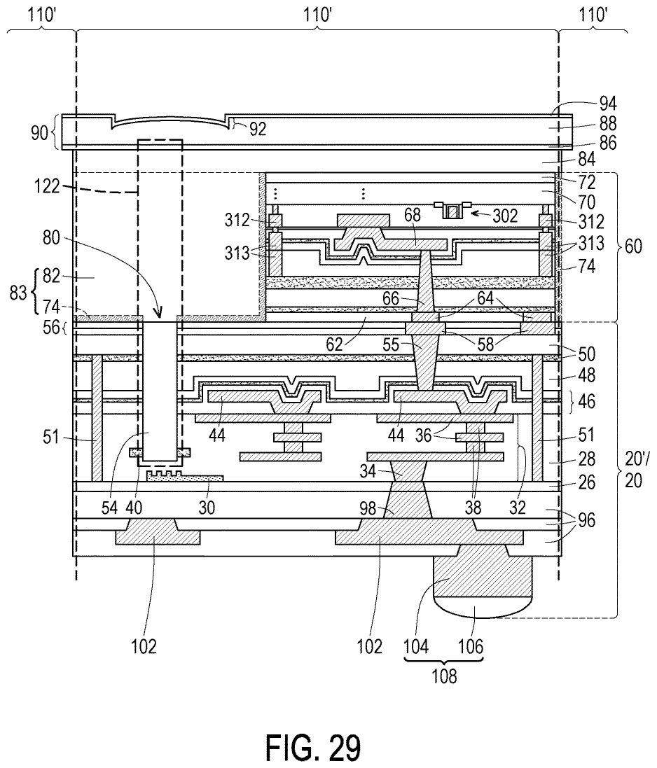

FIG. 29 illustrates the subsequent processes, including the formation of dielectric layers 96, via 98, metal pads 102 and electrical connectors 108. Reconstructed wafer 110 is thus formed.

A singulation process is then performed to saw the reconstructed wafer 110 into a plurality of optical engines 110′. The usage of optical engine 110′ is similar to what is shown in FIG. 12A. In accordance with these embodiments, the optical path of the optical signals received into the optical engine 110′ is formed of essentially the same light-transparent dielectric material (such as silicon oxide), or dielectric materials that have small differences. For example, when silicon oxynitride is used as a part of the optical path along with silicon oxide, the nitrogen atomic percentage may be lower than about 10 percent or 5 percent.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like.

The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By removing the dielectric materials in the optical path and replace with other materials in accordance with some embodiments, the insertion loss is reduced. In accordance with other embodiments, some of the dielectric features such as dielectric barrier may not be formed to reduce the insertion loss.

In accordance with some embodiments of the present disclosure, a method comprises etching a plurality of dielectric layers in a photonic die to form an opening, wherein the opening overlaps a grating coupler, and wherein the photonic die comprises a first top surface at a first level; filling the opening with a first dielectric region; attaching an electronic die to the photonic die, wherein the photonic die comprises a second top surface at a second level; forming a gap-fill region to encircle the electronic die, wherein the gap-fill region comprises a second dielectric region that comprises a first dielectric material, and the first dielectric material extends from the second level to the first level; and bonding a supporting substrate over the gap-fill region and the electronic die, wherein the supporting substrate comprises a micro lens vertically aligned to the grating coupler.

In an embodiment, the forming the gap-fill region comprises depositing a dielectric barrier comprising a second dielectric material different from the first dielectric material; patterning the dielectric barrier to reveal the first top surface of the photonic die; and depositing the second dielectric region over and contacting the dielectric barrier and the first top surface of the photonic die. In an embodiment, after the dielectric barrier is patterned, a remaining horizontal portion of the dielectric barrier remains over the first top surface. In an embodiment, a part of the second dielectric region contacts a remaining horizontal portion of the dielectric barrier. In an embodiment, the first dielectric region and the second dielectric region are deposited in separate processes.

In an embodiment, the patterning the dielectric barrier is performed using a surface layer of the photonic die as an etch stop layer. In an embodiment, the gap-fill region is a barrier-less region, and an entirety of the gap-fill region is formed of the first dielectric material. In an embodiment, the first dielectric material comprises silicon oxide, and the silicon oxide physically contacts the first top surface of the photonic die. In an embodiment, the forming the gap-fill region comprises performing a first deposition process using a first deposition method to deposit the first dielectric material; and performing a second deposition process using a second deposition method different from the first deposition method to further deposit the first dielectric material.

In an embodiment, the forming the gap-fill region comprises depositing a dielectric barrier comprising a second dielectric material over the photonic die and the electronic die; after the dielectric barrier is formed, patterning the dielectric barrier to reveal the first top surface of the photonic die, wherein the etching the plurality of dielectric layers in the photonic die to form the opening is performed after the patterning the dielectric barrier; and performing a deposition process to form both of the first dielectric region and the second dielectric region. In an embodiment, the etching the plurality of dielectric layers in the photonic die to form the opening is performed using a same etching mask as the patterning the dielectric barrier.

In accordance with some embodiments of the present disclosure, a structure comprises a photonic die comprising a grating coupler; and a plurality of dielectric layers higher than the grating coupler, wherein the plurality of dielectric layers comprise a surface dielectric layer; a first dielectric region in the plurality of dielectric layers and encircled by the plurality of dielectric layers, wherein the first dielectric region overlaps the grating coupler; an electronic die over and joined to the photonic die; and a gap-fill region aside of the electronic die, wherein the gap-fill region comprises a second dielectric region comprising a first dielectric material, and the first dielectric material extends at least to a top surface of the photonic die.

In an embodiment, the gap-fill region further comprises a dielectric barrier comprising a vertical portion contacting a sidewall of the electronic die, wherein the vertical portion is between the second dielectric region and the electronic die. In an embodiment, the gap-fill region further comprises a dielectric barrier comprising a horizonal portion contacting the top surface of the photonic die, wherein the horizontal portion is between the second dielectric region and the photonic die.

In an embodiment, the second dielectric region is separated from the first dielectric region by the surface dielectric layer of the photonic die. In an embodiment, entireties of the gap-fill region and the first dielectric region are formed of the first dielectric material, and the first dielectric material is a homogeneous material. In an embodiment, the second dielectric region is continuously joined to the first dielectric region.

In accordance with some embodiments of the present disclosure, a structure comprises a photonic die comprising a plurality of dielectric layers; a first dielectric region in the plurality of dielectric layers; and a first bond layer over the plurality of dielectric layers and the first dielectric region; an electronic die over the photonic die, wherein the electronic die comprises a second bond layer joined to the first bond layer; a dielectric barrier contacting the photonic die and the electronic die; a second dielectric region over the dielectric barrier, wherein the second dielectric region comprises a first portion in the dielectric barrier to contact the first bond layer of the photonic die; and a second portion spaced apart from the first bond layer of the photonic die by the dielectric barrier; and a micro lens over and vertically aligned to the first dielectric region and the first portion of the second dielectric region.

In an embodiment, the first portion of the second dielectric region extends laterally beyond edges of the first dielectric region in a cross-sectional view of the structure. In an embodiment, the second portion of the second dielectric region forms a horizontal interface with the dielectric barrier.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a photonic die comprising a grating coupler;
bonding an electronic die to the photonic die;
depositing a dielectric barrier over the electronic die and the photonic die;
etching the dielectric barrier to form a first opening;
forming a gap-fill region to encapsulate the electronic die, wherein the gap-fill region fills the first opening; and
bonding a supporting substrate over the gap-fill region and the electronic die, wherein the supporting substrate comprises a micro lens, and wherein the first opening in the dielectric barrier is in an optical path between the micro lens and the grating coupler.

2. The method of claim 1, wherein the etching the dielectric barrier is stopped at a top surface of the photonic die.

3. The method of claim 2, wherein the electronic die is bonded to a bond layer of the photonic die, and the top surface of the photonic die is also a top surface of the bond layer.

4. The method of claim 1 further comprising:
performing an etching process to etch a plurality of dielectric layers in the photonic die to form a second opening, wherein the second opening overlaps the grating coupler; and
forming a transparent dielectric region in the second opening.

5. The method of claim 4, wherein the etching process stops at a top surface of an etch stop layer that overlaps the grating coupler.

6. The method of claim 1, wherein the dielectric barrier comprises silicon nitride, and the gap-fill region comprises silicon oxide.

7. The method of claim 1, wherein after the dielectric barrier is etched, remaining horizontal portions of the dielectric barrier remain to be over and contacting the photonic die.

8. The method of claim 7, wherein the remaining horizontal portions of the dielectric barrier are on opposite sides of the first opening.

9. A method comprising:
forming a photonic die comprising a grating coupler;
replacing portions of a plurality of dielectric layers with a transparent region that overlaps the grating coupler;
bonding an electronic die to the photonic die;
depositing a dielectric barrier comprising a first portion over the electronic die, and a second portion over the photonic die;
etching the second portion of the dielectric barrier to form an opening in the second portion, wherein the opening is vertically aligned to the grating coupler;
forming a gap-fill region, wherein the gap-fill region fills the opening; and
planarizing the gap-fill region.

10. The method of claim 9 further comprising bonding a supporting substrate over the gap-fill region and the electronic die, wherein the supporting substrate comprises a micro lens vertically aligned to the opening.

11. The method of claim 9, wherein the dielectric barrier comprises silicon nitride, and the transparent region comprises silicon oxide.

12. The method of claim 9, wherein the second portion of the dielectric barrier physically contacts a top surface of the photonic die.

13. The method of claim 9, wherein the photonic die and the electronic die are comprised in a reconstructed wafer, and the method further comprises sawing the reconstructed wafer.

14. The method of claim 9, wherein the replacing the portions of the plurality of dielectric layers comprises etching the plurality of dielectric layers, wherein the etching is stopped by an etch stop layer in the photonic die.

15. The method of claim 9, wherein the transparent region comprises a bottom surface spaced apart from the grating coupler.

16. The method of claim 9, wherein the dielectric barrier is deposited through a conformal deposition process.

17. A method comprising:
forming a photonic die comprising:
forming a grating coupler;
forming a plurality of dielectric layers over the grating coupler;
etching the plurality of dielectric layers to form a first opening, wherein the etching is stopped at a position higher than and spaced apart from the grating coupler; and
forming a transparent region in the opening;
depositing a barrier layer over and contacting the photonic die;
etching the barrier layer to form a second opening vertically aligned to the transparent region and the grating coupler; and
forming a gap-fill region filling the second opening, wherein the gap-fill region comprises a transparent material.

18. The method of claim 17 further comprising:
bonding an electronic die over the photonic die, wherein the barrier layer further overlaps the electronic die; and
performing a planarization process on the gap-fill region and the electronic die.

19. The method of claim 17, wherein the etching the plurality of dielectric layers is stopped on an etch stop layer.

20. The method of claim 19 further comprising etching-through the etch stop layer.
